(19) United States
(12) Patent Application Publication
(10) Pub. No.: US 2015/0155139 A1
(43) Pub. Date: Jun. 4, 2015

(54) DIELECTRIC WINDOW, ANTENNA AND PLASMA PROCESSING APPARATUS

(71) Applicant: TOKYO ELECTRON LIMITED, Tokyo (JP)

(72) Inventors: Jun YOSHIKAWA, Miyagi (JP); Naoki MATSUMOTO, Miyagi (JP); Masayuki SHINTAKU, Miyagi (JP); Koji KOYAMA, Miyagi (JP); Naoki MIHARA, Miyagi (JP); Yugo TOMITA, Miyagi (JP)

(73) Assignee: TOKYO ELECTRON LIMITED, Tokyo (JP)

(21) Appl. No.: 14/556,596

(22) Filed: Dec. 1, 2014

(30) Foreign Application Priority Data
Dec. 3, 2013 (JP) 2013-250266
Oct. 28, 2014 (JP) 2014-219528

(51) Int. Cl. H01J 37/32; H01P 1/08

(52) U.S. Cl. CPC H01J 37/3222; H01P 1/08; H01J 37/32541; H01J 2237/3348

(57) ABSTRACT

A slot plate is provided at one surface of a dielectric window. The other surface of the dielectric window includes a flat surface surrounded by an annular first recess, and a plurality of second recesses formed at a bottom surface of the first recess. An antenna including the dielectric window and the slot plate provided at one surface of the dielectric window can be applied to the plasma processing apparatus.

### CROSS-REFERENCE TO RELATED APPLICATIONS

This application claims priority to Japanese Patent Application Nos. 2013-250266 and 2014-219528 filed on Dec. 3, 2013 and Oct. 28, 2014, respectively, the entire contents of which are incorporated herein by reference.

### FIELD OF THE INVENTION

The present invention relates to a dielectric window, an antenna, and a plasma processing apparatus.

### BACKGROUND OF THE INVENTION

A conventional plasma processing apparatus is disclosed in, e.g., Japanese Patent Application Publication No. 2007-311668. This plasma processing apparatus is an etching apparatus using a radial line slot antenna. The antenna includes a slot plate and a dielectric plate. A plasma is generated by irradiating a microwave to the antenna.

### SUMMARY OF THE INVENTION

The in-plane uniformity of the plasma thus generated needs to be improved. In view of the above, the present invention provides a dielectric window, an antenna and a plasma processing apparatus which can improve the in-plane uniformity of the plasma.

In accordance with an aspect of the present invention, there is provided a dielectric window having a slot plate at one surface thereof. The other surface of the dielectric window includes a flat surface surrounded by an annular first recess and a plurality of second recesses formed at a bottom surface of the first recess.

With such a configuration, a plasma having high in-plane uniformity can be generated by irradiating a microwave to the antenna. This is because, although a plasma density tends to be increased near the center of the dielectric window, a plasma density at the periphery of the dielectric window can be increased by forming the second recesses 153 at the portion of the first recess which is close to the periphery of the dielectric window. Accordingly, the plasma density becomes uniform over the surface of the dielectric window.

In accordance with another aspect of the present invention, there is provided an antenna including: the dielectric window; and the slot plate provided at the one surface of the dielectric window.

Further, preferably, the slot plate includes a plurality of slot pairs, each being formed of two slots, and the plurality of slot pairs is concentrically arranged about a center of the slot plate and each of the slot pairs is provided at a position where each of the straight lines extending from the center of the slot plate and passing through two slots of each of the slot pairs is not overlapped with each other.

The microwave is incident on the center of the slot plate and radially emitted. If the slot pairs are disposed at positions where straight lines extending from the center of the slot plate and passing through the slot pairs are overlapped with each other, i.e., if the slot pairs are overlapped with each other when seen from the center of the slot plate toward the outer region, the microwave is initially radiated from the slot pair close to the center. Therefore, the microwave having a low electric field intensity propagates to other slot pairs disposed on the straight line extending from the center of the slot plate toward the corresponding slot pair. Accordingly, the microwave having a low electric field intensity is radiated from the other slot pairs. Meanwhile, in the antenna, the slot pairs arranged in a concentric circular shape are provided at positions where the straight lines extending from the center of the slot plate and passing through the slot pairs are not overlapped with each other. In other words, other slot pairs are not provided on the straight line extending from the center of the slot plate and passing through the corresponding slot pair. Accordingly, the slot pairs having a low microwave radiation efficiency for an input power can be eliminated, which makes it possible to relatively improve distribution of the input power to the other slot pairs. As a result, the radiation electric field intensity with respect to the input power is improved and the plasma stability can be improved.

Further, the slot plate may include a first slot group having a plurality of slots spaced from the center of the slot plate by a first distance; a second lot group having a plurality of slots spaced from the center of the slot plate by a second distance; a third slot group having a plurality of slots spaced from the center of the slot plate by a third distance; a fourth slot group having a plurality of slots spaced from the center of the slot plate by a fourth distance, and the first to the fourth distances may have a relationship of the first distance<the second distance<the third distance<the fourth distance; slots of the first slot group and slots of the second slot group which correspond to each other form a plurality of first slot pairs and slots of the third slot group and slots of the fourth slot group which correspond to each other may form a plurality of second slot pairs; the slots of the second slot group of the plurality of the first slot pairs may be positioned on a first straight line extending from the center of the slot plate and passing through the slots of the plurality of the first slot group of the first slot pairs; the slots of the fourth slot group of the plurality of the second slot pairs may be positioned on a second straight line extending from the center of the slot plate and passing through the slots of the plurality of the third slot group of the second slot pairs; and the slots may be arranged such that the first straight line and the second straight line are not overlapped with each other.

With the above configuration, the slot pairs having a low microwave radiation efficiency for the input power can be eliminated, which makes it possible to relatively improve distribution of the input power to the other slot pairs. As a result, the radiation electric field intensity with respect to the input power is improved and the plasma stability can be improved.

Further, when seen from a direction perpendicular to a main surface of the slot plate, the flat surface surrounded by the first recess may be overlapped with the first slot group and the second recesses may be overlapped with at least one of the slots of the third slot group and the slots of the fourth slot group.

In other words, the second recesses are overlapped with the outer slot group (the third slot group or the fourth slot group), so that stable plasma generation can be achieved. This is because the plasma is securely confined in the second recesses and, thus, there are little fluctuation of the plasma and little in-plane variation of the plasma in spite of changes in various conditions.

Further, the number of the slots of the first slot group and the number of the slots of the second slot group may be the same number denoted by N1; and the number of the slots of the third slot group and the number of the slots of the fourth slot group may be the same number denoted by N2, and N2 may be an integer multiple of N1. With this configuration, the plasma having high in-plane symmetry can be generated.

Further, a slot width of the first slot group may be the same as a slot width of the second slot group; a slot width of the third slot group may be the same as a slot width of the fourth slot group; and the slot width of the first slot group and the slot width of the second slot group may be greater than the slot width of the third slot group and the slot width of the fourth slot group.

With the above configuration, the radiation electric field intensity of the first slot group and the second slot group which are close to the center of the slot plate can become lower than that of the third slot group and the fourth slot group which are far from the center of the slot plate. Since the microwave is attenuated during propagation, the radiation electric field intensity of the microwave becomes uniform over the surface of the slot plate by employing the above configuration. Accordingly, the plasma having high in-plane uniformity can be generated.

Further, an angle between a straight line extending from the center of the slot plate and passing through the centers of the slots and a lengthwise direction of the slots may be the same in each of the first to the fourth slot group; the slots of the first slot group and the slots of the second slot group which are positioned on the same straight line extending from the center of the slot plate may be elongated in different directions; and the slots of the third slot group and the slot of the fourth slot group which are positioned on the same straight line extending from the center of the slot plate may be elongated in different directions.

With the above configuration, the reflection in two slots constituting a slot pair is cancelled, so that the uniformity of the radiation electric field intensity of the microwave can be improved.

The second recesses may have a circular shape when seen from the top. When the second recesses have a circular shape, the shape from the center has high uniformity and, hence, stable plasma generation is achieved.

In accordance with still another embodiment of the present invention, there is provided a plasma processing apparatus including: the antenna described above; a processing chamber having the antenna at a ceiling portion thereof; a mounting table, provided in the processing chamber, facing the other surface of the dielectric window, for mounting thereon a substrate to be processed; and a microwave generator configured to supply a microwave to the antenna.

As in the case of the above-described antenna, the plasma processing apparatus can generate a plasma having high in-plane uniformity. Therefore, the uniform processing can be performed over the surface of the substrate to be processed.

In accordance with still another embodiment of the present invention, there is provided an antenna including: the dielectric window described above; and the slot plate provided at the one surface of the dielectric window, and the slot plate includes an inner slot group and an outer slot group which are concentrically arranged about the center of the slot plate; and the outer slot group is provided at both positions overlapped with the second recesses and positions that are not overlapped with the second recesses.

Further, a width of each slot of the inner slot group is about 6 mm±6 mm×0.2 In that case, the stability of the plasma and the misfire preventing function can be improved.

By using the antenna of the dielectric window of the present invention, the in-plane uniformity of the plasma in the plasma processing apparatus can be improved.

### BRIEF DESCRIPTION OF THE DRAWINGS

FIG. 1 is a schematic diagram of a plasma processing apparatus;

FIGS. 2A and 2B are a perspective view and a vertical cross sectional view of a dielectric window in a test example, respectively;

FIGS. 3A and 3B are a perspective view and a vertical cross sectional view of a dielectric window in a comparative example, respectively;

FIG. 4 is a top view of a slot plate provided on the dielectric window;

FIGS. 5A and 5B are views for explaining relation between second recesses and slots;

FIG. 6 is a top view of another slot plate provided on the dielectric window;

FIGS. 7A and 7B are graphs showing whether or not a plasma is stable depending on pressures and powers (FIG. 7A shows a test example of FIG. 4 and FIG. 7B shows a test example of FIG. 6); and

FIGS. 8A and 8B are graphs showing whether or not misfire occurs depending on pressures and powers (FIG. 8A shows the test example of FIG. 4 and FIG. 8B shows the test example of FIG. 6).

### DETAILED DESCRIPTION OF THE EMBODIMENTS

Hereinafter, a dielectric window, an antenna and a plasma processing apparatus in accordance with embodiments of the present invention will be described with reference to the accompanying drawings. Like reference numerals will be used for like parts, and redundant description will be omitted.

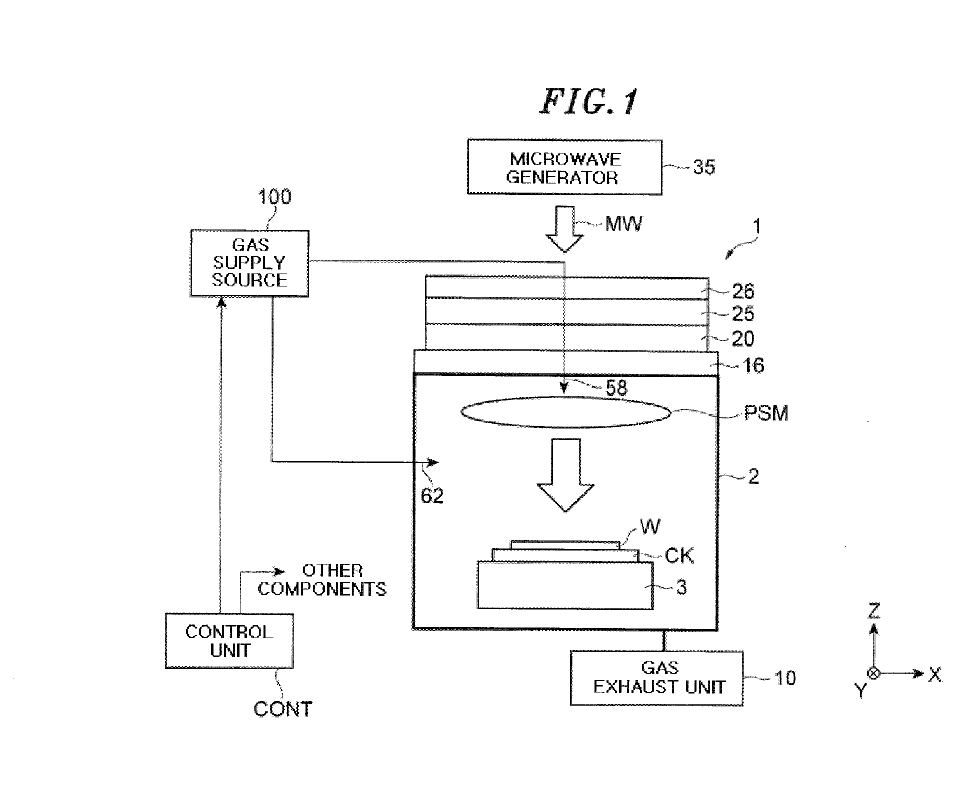

FIG. 1 is a schematic diagram of a plasma processing apparatus.

A plasma processing apparatus 1 includes a cylindrical processing chamber 2. A ceiling portion of the processing chamber 2 is blocked by a dielectric window 16 (ceiling plate) made of a dielectric material. The processing chamber 2 is made of, e.g., aluminum, and is electrically grounded. An inner wall surface of the processing chamber 2 is coated by an insulating protective film such as alumina or the like.

A mounting table 3 for mounting thereon a semiconductor wafer (hereinafter, referred to as “wafer”) as a substrate is provided at a bottom central portion in the processing chamber 2. The wafer W is held on a top surface of the mounting table 3. The mounting table 3 is made of ceramic, e.g., alumina, alumina nitride or the like. A heater (not shown) connected to a power supply is buried in the mounting table 3, so that the wafer W can be heated to a predetermined temperature.

An electrostatic chuck CK for electrostatically attracting the wafer W mounted on the mounting table 3 is provided on the top surface of the mounting table 3. The electrostatic chuck CK is connected to a bias power supply for applying a bias DC current or a high frequency power (RF power) via a matching unit.

Provided at a bottom portion of the processing chamber 2 is a gas exhaust line for exhausting a processing gas through a gas exhaust port disposed at a position lower than the surface of the wafer W mounted on the mounting table 3. A gas exhaust unit 10 such as a vacuum pump or the like is connected to the gas exhaust line. A pressure in the processing chamber 2 is controlled to a predetermined pressure by the gas exhaust unit 10.

The dielectric window 16 is provided at the ceiling portion of the processing chamber 2 through a sealing for ensuring airtightness, such as an O-ring or the like. The dielectric window 16 is made of a dielectric material, e.g., quartz, alumina (Al₂O₃), aluminum nitride (AlN) or the like. The dielectric window 16 transmits a microwave.

A disc-shaped slot plate 20 is provided on a top surface of the dielectric window 16. The slot plate 20 is made of a conductive material, e.g., Cu plated or coated by Ag, Au, or the like. A plurality of slots having a T-shape or an L-shape, for example, is concentrically arranged at the slot plate 20.

A dielectric plate 25 for compressing a wavelength of a microwave is provided on the top surface of the slot plate 20. The dielectric plate 25 is made of a dielectric material, e.g., quartz (SiO₂), alumina (Al₂O₃), aluminum nitride (AlN), or the like. The dielectric plate 25 is covered by a conductive cover 26. An annular heat medium flow path 27 is formed in the cover 26. The cover 2 and the dielectric plate 25 are controlled to a predetermined temperature by a heat medium flowing through the heat medium flow path 27. In case of a microwave of 2.45 MHz, for example, a wavelength in vacuum is about 12 cm and a wavelength in the dielectric window 16 made of alumina is about 3 cm to 4 cm.

A coaxial waveguide (not shown) for propagating a microwave is connected to a center of the cover 26. The coaxial waveguide includes an inner conductor and an outer conductor. The inner conductor is connected to a center of the slot plate 20 while penetrating through a center of the dielectric plate 25. The coaxial waveguide is connected to a microwave generator 35 via a mode converter and a rectangular waveguide. Microwaves of 860 MHZ, 915 MHz or 8.35 GHz may be used instead of the microwave of 2.45 GHz.

A microwave MW generated by the microwave generator 35 propagates to the dielectric plate 25 through the rectangular waveguide, the mode transducer, and the coaxial waveguide, which serve as a microwave introduction path. The microwave MW propagated to the dielectric plate 25 is supplied into the processing chamber 2 through the slots of the slot plate 20 and the dielectric window 16. An electric field is generated below the dielectric window 16 by the microwave and a processing gas in the processing chamber 2 is turned into a plasma. In other words, when the microwave MW is supplied from the microwave generator 35 to the antenna, a plasma is generated.

A lower end of the inner conductor connected to the slot plate 20 has a truncated circular cone shape. The microwave can efficiently propagate from the coaxial waveguide to the dielectric plate 25 and the slot plate 20 without a loss.

The microwave plasma generated by the radial line slot antenna has a feature that a plasma having a relatively high electron temperature which is generated in a region PSM immediately below the dielectric window 16 (hereinafter, referred to as “plasma excitation region”) is diffused downward as indicated by a large arrow and becomes a plasma having a relatively low electron temperature of about 1 eV to 2 eV in a region directly above the wafer W (hereinafter, referred to as “plasma diffusion region”). In other words, unlike the plasma generated by parallel plates or the like, the microwave plasma generated by the radial line slot antenna has a feature that the electron temperature distribution of the plasma is clearly represented by a function of a distance from the dielectric window 16. More specifically, the electron temperature of several eV to about 10 eV in a region directly below the dielectric window 16 decreases to about 1 eV to 2 eV in a region directly above the wafer W. Since the wafer W is processed in the region (plasma diffusion region) where the electron temperature of the plasma is low, e.g., a recess or the like which may damage the wafer W is reduced. If the processing gas is supplied to the region (plasma exciting region) where the electron temperature of the plasma is high, the processing gas is easily excited and dissociated. If the processing gas is supplied to the region where the electron temperature of the plasma is low (the plasma diffusion region), the degree of dissociation is decreased compared to the case where the processing gas is supplied to the vicinity of the plasma exciting region.

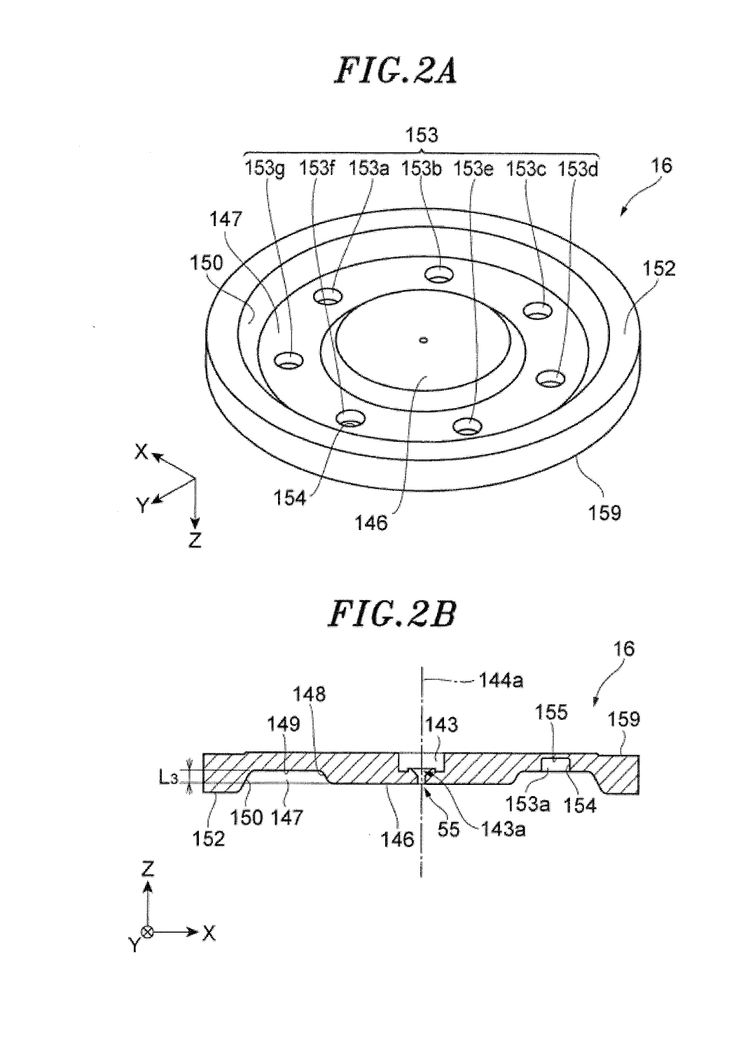

A central introduction unit 55 (see FIG. 2B) for introducing the processing gas to the cent ral portion of the wafer W is provided at the center of the dielectric window 16 at the ceiling portion of the processing chamber 2. The central introduction unit is connected to a processing gas supply line. The processing gas supply line is formed in the inner conductor of the coaxial waveguide.

The central introduction unit includes a cylindrical block (not shown) inserted into a cylindrical space 143 (see FIG. 2B) provided at the center of the dielectric window 16 and a tapered space 143a (see FIG. 2B) continuous to a cylindrical space having a gas injection opening at a leading end thereof. The block is made of a conductive material, e.g., aluminum or the like, and is electrically grounded. The block made of aluminum may be coated by anodically oxidized alumina (Al₂O₃), yttria (Y₂O₃) or the like. A plurality of central inlet openings 58 penetrates through the block in a vertical direction. A gap (gas storage) exists between the top surface of the block and the bottom surface of the inner conductor of the coaxial waveguide. The central inlet openings 58 have a circular or elongated hole shape when seen from the top in consideration of a required conductance or the like.

The shape of the space 143a is not limited to a tapered shape and may be simply a cylindrical shape.

The processing gas supplied into the gas storage above the block is diffused in the gas storage and then injected downward toward the central portion of the wafer W through the central inlet openings of the block.

In the processing chamber 2, a ring-shaped peripheral introduction unit for supplying a processing gas to a peripheral portion of the wafer W is provided to surround the periphery of the space above the wafer W. The peripheral introduction unit is positioned below the central inlet openings 58 formed at the ceiling portion and above the wafer W mounted on the mounting table 3. The peripheral introduction unit is an annular hollow pipe. A plurality of peripheral inlet openings 62 spaced apart from each other at a regular interval in a circumferential direction is formed at an inner peripheral side of the peripheral inlet unit. The processing gas is injected through the peripheral inlet openings 62 toward the center of the peripheral introduction unit. The peripheral introduction unit is made of, e.g., quartz. A supply line made of stainless steel penetrates through the sidewall of the processing chamber 2. The supply line is connected to the peripheral inlet openings 62 of the peripheral introduction unit. The processing gas supplied into the peripheral introduction unit through the supply line is injected toward the inner side of the peripheral introduction unit through the peripheral inlet openings 62. The processing gas injected through the peripheral inlet openings 62 is supplied to a space above the peripheral portion of the wafer W. Instead of providing the ring-shaped peripheral introduction unit, a plurality of peripheral inlet openings 62 may be formed at the inner surface of the processing chamber 2.

The processing gas is supplied from the gas supply source 100 to the central inlet opening 58 and the peripheral inlet opening 62. A gas supply source 100 includes a common gas source and an additional gas source and supplies processing gases for various processes such as plasma etching, plasma CVD processing and the like. A desired processing gas can be obtained by mixing gases from a plurality of gas sources while controlling flow rates thereof using flow rate control valves provided in the respective supply lines. The flow rate control valves can be controlled by a control unit CONT. The control unit CONT also controls starting of the microwave generator 35, heating of the wafer W, evacuation using the gas exhaust unit 10 or the like.

The processing gases from the common gas source and the additional gas source are mixed at a ratio suitable for the purpose and supplied to the central inlet opening 58 and the peripheral inlet opening 62.

For example, a rare gas (Ar gas or the like) may be used as a gas from the common gas source. However, other additional gases may also be used. In the case of etching a silicon-based film such as polysilicon or the like, Ar gas, HBr gas (or Cl₂ gas), and 02 gas are supplied as the additional gas. In the case of etching an oxide film such as SiO₂ or the like, Ar gas, CHF-based gas, CF-based gas, and O₂ gas are supplied as the additional gas. In the case of etching a nitride film such as SiN or the like, Ar gas, CF-based gas, CHF-based gas, and O₂ gas are supplied as the additional gas.

The CHF-based gas may include CH₃(CH₂)₃CH₂F, CH₃ (CH₂)₄CH₂F, CH₃ (CH₂)₇CH₂F, CHCH₃F₂, CHF₃, CH₃F, CH₂F₂ or the like.

Although the CF-based gas may be C(CF₃)₄, C(C₂F₅)₄, C₄F₈, C₂F₂, C₅F₈ or the like, it is preferable to use C₅F₈ in order to obtain dissociated species suitable for the etching.

A central inlet gas Gc is supplied to the central inlet opening 58. A peripheral inlet gas Gp is supplied to the peripheral inlet opening 62. In this apparatus, it is possible to change gas types or partial pressures of the central inlet gas Gc supplied to the central portion of the wafer W and the peripheral inlet gas Gp supplied to the peripheral portion of the wafer W, so that the characteristics of the plasma treatment can be variously modified. In this apparatus, the same gas may be supplied from the common gas source and the additional gas source, or different gases may be supplied from the common gas source and the additional gas source.

In order to suppress dissociation of the etching gas, a plasma excitation gas may be supplied from the common gas source and an etching gas may be supplied from the additional gas source. For example, in the case of etching a silicon-based film, only Ar gas is supplied as the plasma excitation gas from the common gas source and HBr gas and O₂ gases are supplied as etching gases from the additional gas sources. The common gas source may supply a common gas such as O₂, SF₆ or the like other than a cleaning gas.

The above-described gas contains a so-called negative gas. The negative gas denotes a gas having an electron attachment cross section area at an electron energy of about 10 eV or less, e.g., HBr, SF₆ or the like.

Here, in order to achieve uniform plasma generation and uniform processing over the surface of the wafer W, a technique that controls a distribution ratio of the common gas by using the flow splitter and controls the amount of gases introduced from the central inlet opening 58 and the peripheral inlet opening 62 is referred to as “RDC (Radical Distribution Control)”. The RDC value is expressed as a ratio of the amount of gas introduced from the central inlet opening 58 with respect to the amount of gas introduced from the peripheral inlet opening 62. In general RDC, the same gas is supplied from the central inlet opening 58 and the peripheral inlet opening 62 into the chamber. An optimum RDC value is determined experimentally depending on types of films to be etched or various conditions.

In the etching process, by-products (etching residue or deposits) are generated by the etching. In order to improve gas flow in the processing chamber 2 and easily discharge the by-products to the outside of the processing chamber, it is considered to alternately introduce gases from the central inlet opening 58 and the peripheral inlet opening 62. This can be realized by switching a RDC value temporally. For example, the by-products are removed from the processing chamber 2 by repeating a step of introducing a large amount of gas to the central portion of the wafer W and a step of introducing a large amount of gas to the peripheral portion of the wafer W at a predetermined cycle and controlling gas flow. Accordingly, a uniform etching rate can be obtained.

The plasma processing apparatus shown in FIG. 1 is a general apparatus using a slot plate and may be variously modified. The slot plate 20 forms the antenna together with the dielectric window 16. Next, the dielectric window 16 forming the antenna will be described.

FIGS. 2A and 2B are a perspective view and a vertical cross sectional view of a dielectric window in accordance with an embodiment of the present invention, respectively. In FIG. 2A, an upside-down state of the dielectric window is illustrated so that the structure of the recesses can be seen.

The dielectric window 16 has a substantially disc shape and has a predetermined plate thickness. The dielectric window 16 is made of a dielectric material. Specifically, the dielectric window 16 is made of quartz, alumina or the like. The slot plate 20 is provided on a top surface 159 of the dielectric window 16.

A through-hole is formed at the center of the dielectric plate 16 in a diametrical direction thereof to extend through the dielectric plate 16 in a plate thickness direction thereof, i.e., in a vertical direction in the drawing. A lower region of the through-hole serves as a gas supply port of the central introduction unit 55 and an upper region of the through-hole serves as a recess 143 where the block of the central introduction unit 55 is disposed. A central axis 144a of the dielectric window 16 in the diametrical direction is indicated by a dashed dotted line in FIG. 2B.

An annular first recess 147 that is tapered inwardly in the plate thickness direction of the dielectric window 16 is formed at an outer region of a flat surface 146 in the diametrical direction. The flat surface 146 is disposed at the bottom surface of the dielectric window 16 where the plasma is generated when the dielectric window 16 is attached to the plasma processing apparatus. The flat surface 146 is disposed at a central region of the dielectric window 16 in the diametrical direction. Circular second recesses 153 (153a to 153g) spaced from each other at a regular interval along the circumferential direction are formed at a bottom surface 149 of the first recess 147. The annular first recess 147 includes: an inner tapered surface 148 tapered outward from the peripheral region of the flat surface 146, i.e., inclined with respect to the flat surface 146; a flat bottom surface 149 extending straightly outward from the inner tapered surface 148, i.e., in parallel to the flat surface 146; and an outer tapered surface 150 extending outward from the bottom surface 149, i.e., inclined with respect to the bottom surface 149.

Angles of the tapered surfaces, e.g., an angle defined in an extension direction of the inner tapered surface with respect to the bottom surface 149 and an angle defined in an extension direction of the outer tapered surface 150 with respect to the bottom surface 149, are randomly set. In the present embodiment, the angles are the same at any position in the circumferential direction. The inner tapered surface 148, the bottom surface 149, and the outer tapered surface 150 extend as smooth curved surfaces. Further, an outer peripheral flat surface 152 extending straightly outward in the diametrical direction, i.e., in parallel to the flat surface 146, is provided at an outer side of the outer tapered surface 150.

The outer peripheral flat surface 152 serves as a supporting surface of the dielectric window 16 and closes an opening end surface of the processing chamber 2. In other words, the dielectric window 16 is attached to the processing chamber 2 such that the outer peripheral flat surface 152 is disposed at an upper end surface of the cylindrical processing chamber 2.

Due to the presence of the annular first recess 147, a region where the thickness of the dielectric window 16 is continuously changed is formed at the outer region of the dielectric window 16 in the diametrical direction. Accordingly, a resonance region where the dielectric window 16 has a thickness suitable for various processing conditions for plasma generation can be formed. As a result, high stability of the plasma can be obtained at the outer region in the diametrical direction under various processing conditions.

In the dielectric window 16, the second recesses 153 (153a to 153g) recessed inwardly in the plate thickness direction are formed at the bottom surface of the annular first recess 147. Each of the second recesses 153 has a circular shape in a plane view. Each of the second recesses 153 has a cylindrical side surface and a flat bottom surface 155. Since a circle is a polygon having infinite corners, the second recesses 153 may have a polygonal shape having finite corners in a plane view. It is considered that the plasma is generated in the recess during introduction of microwaves. When the recess has a circular shape when seen from the top, the shape from the center has high uniformity, so that the plasma can be stably generated.

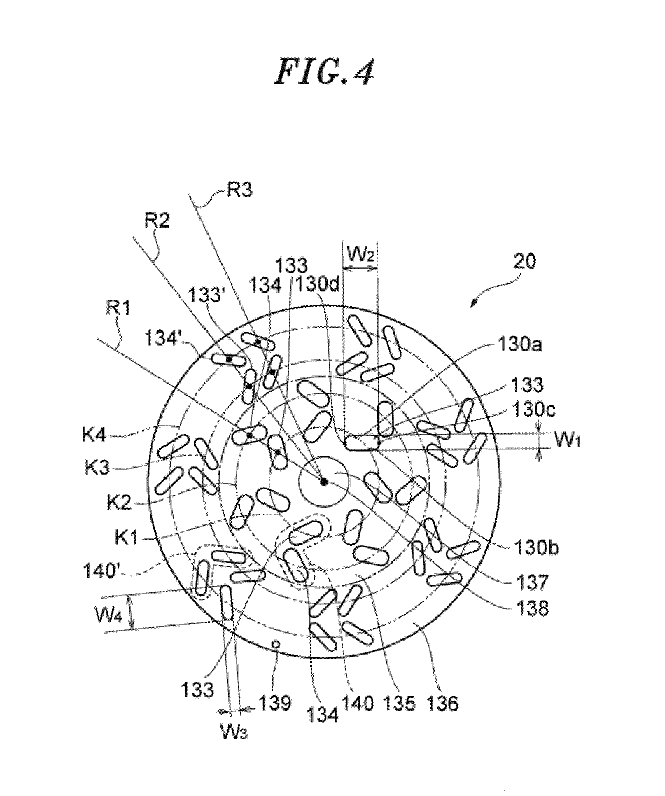

In the present embodiment, the total number of the second recesses 153 is seven. The number of the second recesses 153 is equal to that of the outer slot pairs (see FIG. 4). The seven second recesses 153a, 153b, 153c, 153d, 153e, 153f, and 153g have the same shape, the same depth, the same diameter, and the like. The seven second recesses 153a to 153g are spaced from each other at a regular interval to have rotation symmetry about the centroid of the dielectric window 16 in the diametrical direction (central axis 144a shown in FIG. 2B) as the center. When seen from the plate thickness direction of the dielectric window 16, centroids (referred to as G2) of the circular seven second recesses 153a to 153g are positioned on a circle having, as its center, the center of the dielectric window 16 (the central axis 144a). In other words, even if the dielectric window 16 is rotated by about 51.42 (=360°/7) about the center of the dielectric window 16 (the central axis 144a) on the XY plane, the same shape as that before the rotation is obtained.

In the present embodiment, a diameter of a circle passing through all of the centroids of the second recesses 153 is about 143 mm; a diameter of the second recesses 153 is about 50 mm; and a depth of the second recesses 153 from the bottom surface of the first recess 147 is about 10 mm. A depth L₃ from the flat surface 146 of the first recess 147 is properly set. It is set to about 32 mm in the present embodiment.

The diameter of the second recesses 153 and the distance from the bottom surface 155 of the second recesses 153 to the top surface of the dielectric window 163 are set to be, e.g., about ¼ of a wavelength λg of the microwave introduced thereinto. In the present embodiment, the diameter of the dielectric window 16 is about 460 mm. It may vary within a range of about ±10%. However, conditions for operating the apparatus are not limited thereto and the apparatus can operate as long as the plasma is confined in the recesses.

The plasma density tends to be high near the center of the dielectric window 16. In the present embodiment, the plasma density at the periphery of the dielectric window 16 can become higher than that at the center of the dielectric window 16 by forming the second recesses 153 near the periphery of the dielectric window 16. As a result, the plasma density becomes uniform over the surface of the dielectric window 16.

Due to the presence of the second recesses 153a to 153g, the electric field of the microwave can concentrate in the recess and a mode can be securely fixed at the inner region of the dielectric window 16 in the diametrical direction. In this case, since the region where the mode is securely fixed can be obtained at the inner region of the dielectric window 16 in the diametrical direction even if various processing conditions are changed, the plasma can be stably and uniformly generated. Accordingly, the substrate can be uniformly processed over the surface. Especially, the second recesses 153a to 153g have rotation symmetry, so that the region where the mode is securely fixed can have high axial symmetry at the inner region of the dielectric window 16 in the diametrical direction. As a result, the generated plasma has axial symmetry.

The dielectric window 16 configured as described above has a wide range of process margin and the generated plasma has high axial symmetry.

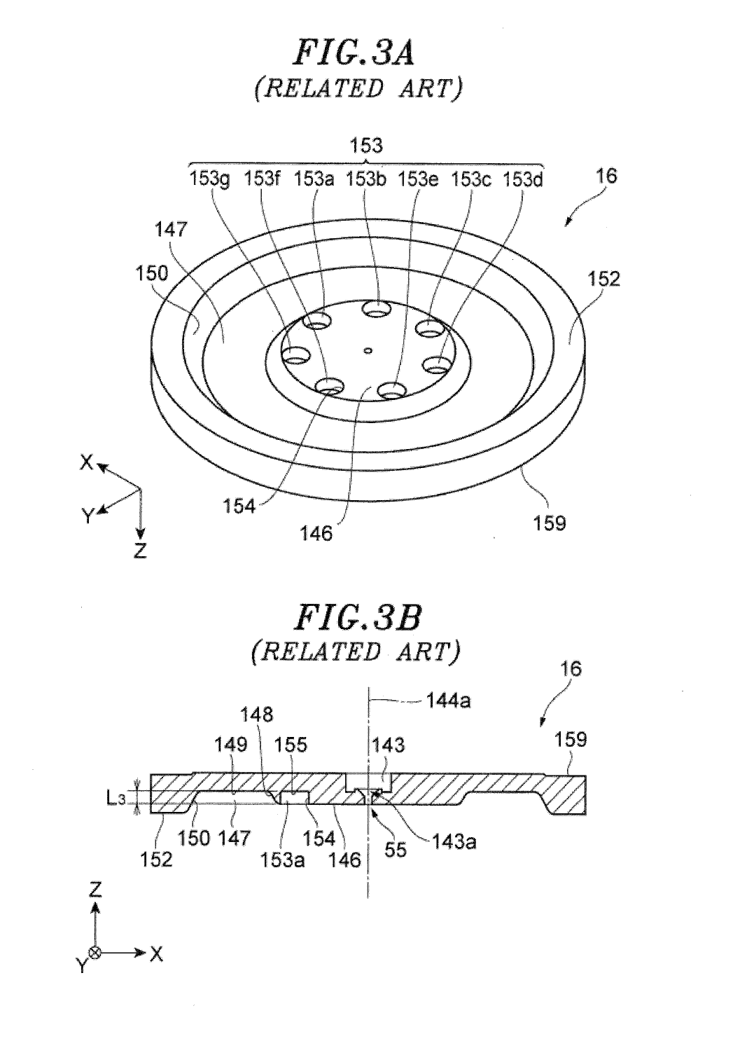

FIGS. 3A and 3B are a perspective view and a vertical cross sectional view of the dielectric window of a comparative example, respectively.

The dielectric window 16 of the comparative example is different from the dielectric window 16 shown in FIGS. 2A and 2B in that the second recesses 153 are formed on the central flat surface 146. The other structures are the same as those shown in FIGS. 2A and 2B.

In the comparative example, the plasma intensity near the center of the dielectric window 16 (see FIG. 3) is high and, thus, the in-plane uniformity of the plasma density is insufficient.

An oxide film (SiO₂) was etched by using the plasma processing apparatus including the dielectric window (see FIGS. 2A and 2B) of the present embodiment and the plasma processing apparatus including the dielectric window (see FIGS. 3A and 3B) of the comparative example.

In this test, there were used the antenna obtained by combining the dielectric window of the present embodiment and the slot plate shown in FIG. 4 and the antenna obtained by combining the dielectric window of the comparative example and the slot plate shown in FIG. 4. Further, the oxide film was etched under the following conditions. A pressure in the processing chamber was set to 20 mTorr (2.6 Pa). Ar (flow rate: 500 sccm), He (flow rate: 500 sccm), C₄F₆ (flow rate: 20 sccm) and O₂ (flow rate: 3 sccm) were used as processing gases. A RDC value for introducing the processing gas was set to 50 (the amount of gas introduced from the central inlet opening 58 was set to 50% and the amount of gas introduced from the peripheral inlet opening 62 was set to 50%). A temperature of the mounting table 3 was set to about 50° C. The plasma was stably generated when the dielectric window (see FIGS. 2A and 2B) of the present embodiment and the slot plate 20 were combined such that the second recesses 153 (see FIG. 2) were overlapped with at least one of the third slots 133′ (see FIG. 4) and the fourth slots 134′ (see FIG. 4). In this test, they were combined such that the second recesses 153 were overlapped with both of the third slots 133′ and the fourth slots 134′.

According to five tests, the deviation ((maximum etching amount-minimum etching amount)/(2×average etching amount)×100) of the etching amount was about ±1.9%, ±2.0%, ±1.8%, ±1.6% in the present embodiment. However, the deviation of the etching amount in the comparative example was about ±11.3%. In other words, the deviation of the etching amount in the present embodiment was about ±2% or less, which was excellent compared to that in the comparative example.

FIG. 4 is a top view of the slot plate provided on the dielectric window.

The slot plate 20 has a thin circular plate shape. Both surfaces of the slot plate 20 in a plate thickness thereof are flat. The slot plate 20 has a plurality of slots penetrating therethrough in the plate thickness direction. A first slot 133 elongated in one direction and a second slot 134 elongated in a direction perpendicular to the first slot 133 form a pair. Specifically, two slots 133 and 134 adjacent to each other form a pair and are arranged in a substantially L-shape that is disconnected at a central portion. In other words, the slot plate 20 has slot pairs 140, each being formed of the first slot 133 extending in one direction and the second slot 134 extending in a direction perpendicular thereto. In the same manner, a slot pair 140′ is formed of a third slot 133′ and a fourth slot 134′. Examples of the slot pairs 140 and 140′ are illustrated in a region indicated by dotted lines in FIG. 4.

The slot pair is divided into an inner peripheral slot pair group 135 disposed at an inner peripheral side and an outer peripheral slot pair group 136 disposed at an outer peripheral side. The inner peripheral slot pair group 135 has seven slot pairs 140 provided in an inner region of a virtual circle indicated by a dashed dotted line in FIG. 4. The outer peripheral slot pair group 136 has fourteen slot pairs 140′ provided in an outer region of the virtual circle indicated by the dashed dotted, line in FIG. 4. The slot pairs 140 and 140′ are disposed in a concentric circular shape to surround the center 138 (centroid position) of the slot plate 20 (corresponding to the central axis 144a of the dielectric window 16 (see FIG. 2B).

The dielectric window 16 and the slot plate 20 are coaxially arranged.

In the outer peripheral slot pair group 136, the fourteen slot pairs 140′ are grouped into seven sets, each being formed of two slot pairs adjacent to each other in the circumferential direction, and the seven sets are spaced from each other at a regular interval in the circumferential direction. With such a configuration, each set for the fourteen slot pairs 140′ of the outer peripheral slot pair group 136 can be arranged at a position corresponding to the position of each of the second recesses that are circular dimples, such that any slot of each set overlaps with the corresponding second recess.

The outer peripheral slot pair group 136 is provided not to overlap with the inner peripheral slot pair group 135 when seen from the center 138 of the slot plate 20 in the diametrical direction toward the outer region. Therefore, in the outer peripheral slot pair group 146, the seven sets, each being formed of two slot pairs 140′, are spaced from each other at a regular interval in the circumferential direction.

In the present embodiment, an opening width of the first slot 133, i.e., a distance W₁ between one wall 130a and the other wall 130b extending in the lengthwise direction of the first slot 133, is set to 14 mm. Meanwhile, a length of the first slot 133, i.e., a length between one end 130c and the other end 130d of the first slot 133 in the lengthwise direction which is denoted by W₂ in FIG. 4, is set to 35 mm. Although the width W₁ and the length W₂ may be changed within a range of ±10%, the apparatus can operate even when the width and the length are not within such ranges. A ratio W₁/W₂ of the short side to the long side in the first slot 133 is 14/35=0.4. The opening shape of the first slot 133 is the same as that of the second slot 134. In other words, if the first slot 133 is rotated at an angle of 90°, the second slot 134 is completely overlapped with the rotated first slot 133. When an elongated hole such as a slot is formed, the length ratio W₁/W₂ is smaller than about 1.

Meanwhile, an opening width W₃ of the fourth slot 134′ is smaller than an opening width W₁ of the first slot 133. In other words, the opening width W₁ of the first slot 133 is larger than the opening width W₃ of the fourth slot 134′. Here, the opening width W₃ of the fourth slot 134′ is, e.g., 10 mm. A length of a long side of the fourth slot 134′ which is denoted by W₄ in FIG. 4 is the same as the length W₂ of the first slot 133. Although the width W₃ and the length W₄ may be changed within a range of ±10%, the apparatus operates even when the width and the length are not within such ranges. A ratio W₃/W₄ of the short side to the long side in the fourth slot 134′ is 10/35≈0.29. The opening shape of the fourth slot 134′ is the same as that of the third slot 133′. In other words, if the third slot 133′ is rotated at an angle of 90°, the fourth slot 134′ is completely overlapped with the rotated third slot 133′. When a long hole such as a slot is formed, the length ratio W₃/W₄ is smaller than about 1.

A through-hole 137 is formed at the center of the slot plate 20 in the diametrical direction. A reference hole 139 is formed through the slot plate 20 in the plate thickness direction thereof at a radially outer region of the outer peripheral slot pair group 136 in order to allow the slot plate 20 to be easily positioned in the circumferential direction thereof. In other words, the position of the slot plate 20 in the circumferential direction with respect to the processing chamber 2 or the dielectric window 16 is determined while using the reference hole 139 as a mark. The slot plate 20 has rotation symmetry about the center 138 in the diametrical direction except the reference hole 139.

Next, the structure of the slot plate 20 will be described in detail. The slot plate 20 includes: a first slot group 133 spaced from the centroid position 138 of the slot plate 20 by a first distance K1 (indicated by a circle K1); a second slot group 134 spaced from the centroid position 138 by a second distance K2 (indicated by a circle K2); a third slot group 133′ spaced from the centroid position 138 by a third distance K3 (indicated by a circle K3); and a fourth slot group 134′ spaced from the centroid position 138 by a fourth distance K4 (indicated by a circle K4).

Here, the first to the fourth distances K1 to K4 have a relationship of K1<K2<K3<K4. Angles between lengthwise directions of the slots 133, 134, 133′ and 134′ and straight lines (a first straight line R1 and a second straight line R2 or R3) extending from the centroid position 138 of the slot plate and passing through the centroids of the slots are the same in each of the first to the fourth slot group 133, 134, 133′ and 134′.

The slot 133 of the first slot group and the slot 134 of the second slot group which are positioned on the same straight line (the first straight line R1) extending from the centroid position 138 of the slot plate 20 are elongated in different directions (orthogonally in this example). The slot 133′ of the third slot group and the slot 134′ of the fourth slot group which are positioned on the same straight line (the second straight line R2 or R3) extending from the centroid position 138 of the slot plate 20 are elongated in different directions (orthogonally in this example). The slots 133, 134, 133′, 134′ are arranged such that the straight line R1 and the straight line R2 are not overlapped with each other or the straight line R1 and the straight line R3 are not overlapped with each other. For example, the angle between the straight line R1 and the straight line R2, or the angle between the straight line R1 and the straight line R3 is greater than or equal to about 10°. With such a configuration, the slots having a low microwave radiation efficiency for the input power can be eliminated, which makes it possible to relatively improve distribution of the input power to the other slots. As a result, the radiation electric field intensity with respect to the input power is improved and the plasma stability can be improved.

The number of the slots 133 of the first slot group and the number of the slots 134 of the second slot group are the same (N1). The number of the slots 133′ of the third slot group and the number of the slots 134′ of the fourth slot group are the same (N2). N2 is an integer multiple of N1. With this configuration, a plasma having high in-plane symmetry can be generated.

As described above, a negative gas has an electron attachment cross section area at the electron energy of about 10 eV or less. Therefore, the negative gas is easily turned into negative ions due to attachment of electrons in the plasma diffusion region. In other words, in the plasma processing using a negative gas, electrons and negative ions simultaneously exist as negative charges in the plasma. When the electrons are attached to the negative gas, loss is caused. In order to maintain stability of a plasma, it is required to increase the number of electrons that are generated to compensate the loss. Accordingly, in the plasma processing using a negative gas, the electric field intensity needs to be improved compared to the case of using other gases. In the antenna and the plasma processing apparatus of the present embodiment, the radiation electric field intensity with respect to the input power can be improved. Hence, the stability of the plasma can be improved even in the case of using a negative gas. Especially, it is expected that an etching process inflicts less damage at a pressure range from an intermediate pressure (e.g., 50 mTorr (6.5 Pa)) in which negative ions are easily generated to a high pressure.

In the antenna and the plasma processing apparatus of the present embodiment, the slot width W₁ of the first slot group and the second slot group is greater than the slot width W₃ of the third slot group and the fourth slot group. As the opening width of the slot is increased, the electric field of the introduced microwave is decreased. When the opening width of the slot is decreased, the microwave can be strongly radiated. Therefore, it is possible to lower the radiation electric field intensity of the first slot group and the second slot group near the center 138 of the slot plate 20 than that of the third slot group and the fourth slot group far from the center 138 of the slot plate 20. The microwave is attenuated during propagation. Therefore, the radiation electric field intensity of the microwave becomes uniform over the surface of the slot plate by employing the above-described configuration. As a result, a plasma having high in-plane uniformity can be generated.

In the antenna and the plasma processing apparatus of the present embodiment, when seen from a direction perpendicular to the main surface of the slot plate 20, the centroid positions of the second recesses 153 are positioned in the slots 133 of the slot plate 20. Accordingly, the plasma having high uniformity can be generated and the in-plane uniformity of the processing amount can be improved. Such a plasma processing apparatus may be used for film deposition as well as etching

While various embodiments have been described, the present invention may be modified without being limited to the above embodiments. For example, although the above embodiments have described an example in which the slot pairs are arranged in the form of two concentric circular rings, the slot pairs may be arranged in the form of three or more circular rings.

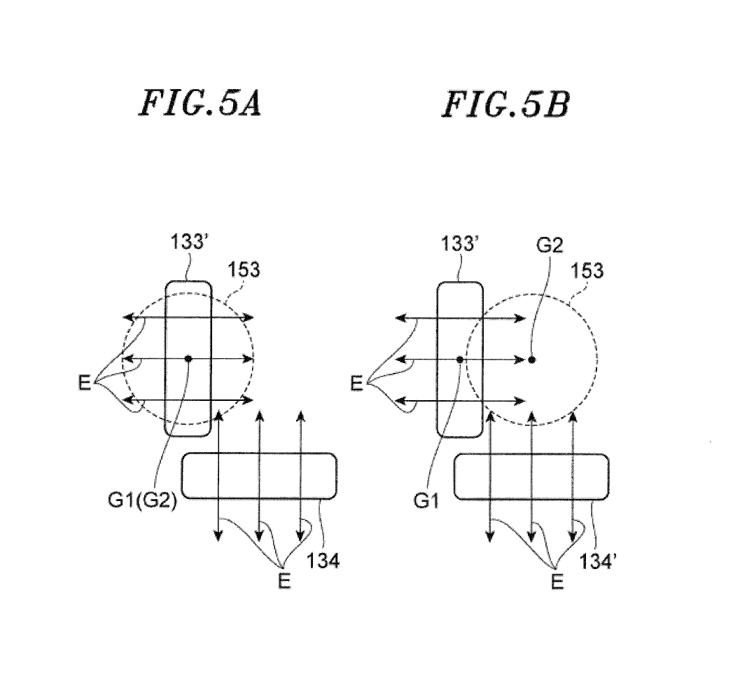

FIGS. 5A and 5B are views for explaining relation between the second recesses and the slots.

FIG. 5A shows the case where the centroid G2 of the second recess 153 is set to a position where the electric field E from the slot 133′ is selectively introduced. Due to the introduction of the microwave, the electric field E is generated in the width direction of the slots 133′ and 134′. In this example, the centroid position G1 of the slot 133′ and the centroid G2 of the second recess 153 coincide with each other, and the centroid G2 of the second recess 153 is positioned to overlap with the slot 133′. In this case, the plasma is securely confined in the second recess 153, so that there are little fluctuation in the plasma state and little in-plane variation of the plasma state in spite of changes in various conditions. Especially, since the second recesses 153 are formed at the bottom surface of the first recess, the surface around one recess 153 has high equivalence and, thus, the degree of plasma confinement becomes high.

Meanwhile, FIG. 5B shows the case where the centroid G2 of the second recess 153 is set to a position where the electric fields E from the slots 133′ and 134′ are introduced. In other words, in FIG. 5B, the centroid position G1 of the slot 133′ is separated from the center G2 of the second recess 153 and the centroid G2 of the second recess 153 is positioned not to overlap with the slot 133′. In this case, the microwaves are not easily introduced into the recess 153 compared to the case shown in FIG. 5A, so that the plasma density is decreased.

When seen from a direction perpendicular to the main surface of the slot plate 20, the flat surface 146 (see FIGS. 2A and 2B) surrounded by the first recess 147 is overlapped with the first slot group 133 (see FIG. 4).

The second recesses 153 are overlapped with the slots of the third slot group 133′ or the slots of the fourth slot group 134′. In other words, the outer slot group (the third slot group or the fourth slot group) is overlapped with the second recesses 153, so that a plasma can be stably generated. This is because the plasma is reliably confined in the recesses 153, so that there are little fluctuation in the plasma state and little in-plane variation of the plasma state in spite of changes in various conditions.

As described above, the slot plate 20 is provided at one surface of the dielectric window 16. Formed at the other surface of the dielectric window 16 are the flat surface 146 surrounded by the annular first recess 147 and the second recesses 153 (153a to 153g) formed at the bottom surface of the first recess 147. The antenna including the dielectric window 16 and the slot plate 20 provided at one surface of the dielectric window 16 can be applied to the plasma processing apparatus.

The plasma processing apparatus includes: the antenna; the processing chamber having therein the antenna; the mounting table, provided in the processing chamber to face the other surface of the dielectric window, for mounting thereon a substrate to be processed; and the microwave generator for supplying a microwave to the antenna. Such a plasma processing apparatus can improve the in-plane uniformity of the plasma.

Another slot plate may be used instead of the above-described slot plate.

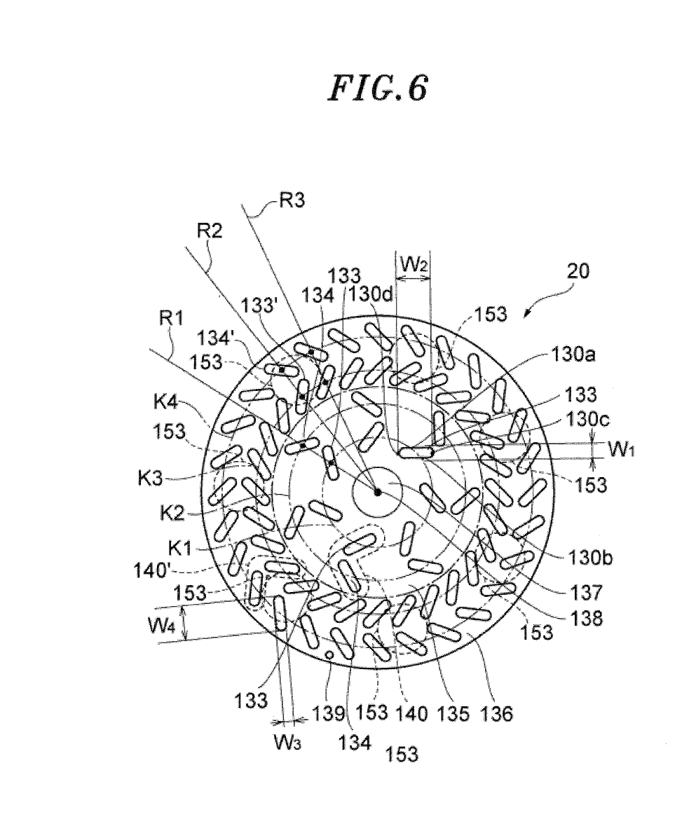

FIG. 6 is a top view of another slot plate provided on the dielectric window.

The slot plate shown in FIG. 6 is different from that shown in FIG. 4 in the following characteristics (1) and (2). The other structures are the same.

In other words, (1) the width W₁ of the inner slots 133 and 134 is smaller than that shown in FIG. 4, so that a condition of W₁=W₃ or W₁<W₃ is satisfied. By reducing the width of the inner slots 133 and 134, it is expected that at least a plasma mode becomes stable. Further, the width of the outer slots 133′ and 134′ is set to be substantially the same as that of the inner slots 133 and 134. By reducing the width of the slot, especially by reducing the width W₁ of the inner slots 133 and 134, it is expected that the plasma mode becomes stable. This is because a maximum electric field of a standing wave formed by the slots tends to be increased when the slot width is reduced. When the electric field intensity is increased, the possibility of plasma generation at that portion is increased. This results in suppression of plasma generation at other portions. In other words, it is difficult to shift the mode. In other words, the stability of the plasma is improved and the occurrence of misfire is reduced. Next, the number of modes will be described. If the number of dominant modes is large, the electric field intensity varies among the modes. Thus, it is difficult to restrict a plasma generation area depending on plasma conditions, which makes the plasma unstable. When the number of the inner slots is smaller than that of the outer slots, i.e., when the width of the inner slots is reduced, the generation of plasma by the inner slots becomes dominant. Hence, the plasma generation area is decreased and the mode is not easily shifted. Accordingly, the mode locking is promoted and this leads to improvement of the stability. It is preferable that the width satisfies a condition of W₁=W₃=6 mm. However, the same effect can be expected even when the width satisfies a condition of W₁=W₃=6 mm±6 mm×0.2 while considering an error of 20%. This is because the maximum intensity of the electric field generated by the slots is not considerably affected within such an error range.

(2) The number of the outer slots 133′ and 134′ is doubled. Twenty-eight pairs of the outer slots 133′ and 134′ are arranged at a regular interval along the circumferential direction. When seen from the top, the outer slots 133′ and 134′ are overlapped with the recesses 153 and provided at positions where the recesses 153 are not formed. Accordingly, the mode locking is expected even at a location where the recesses 153 are not formed.

In the present embodiment, due to the characteristics (1) and (2), the plasma becomes stable and the occurrence of misfire due to the plasma is suppressed.

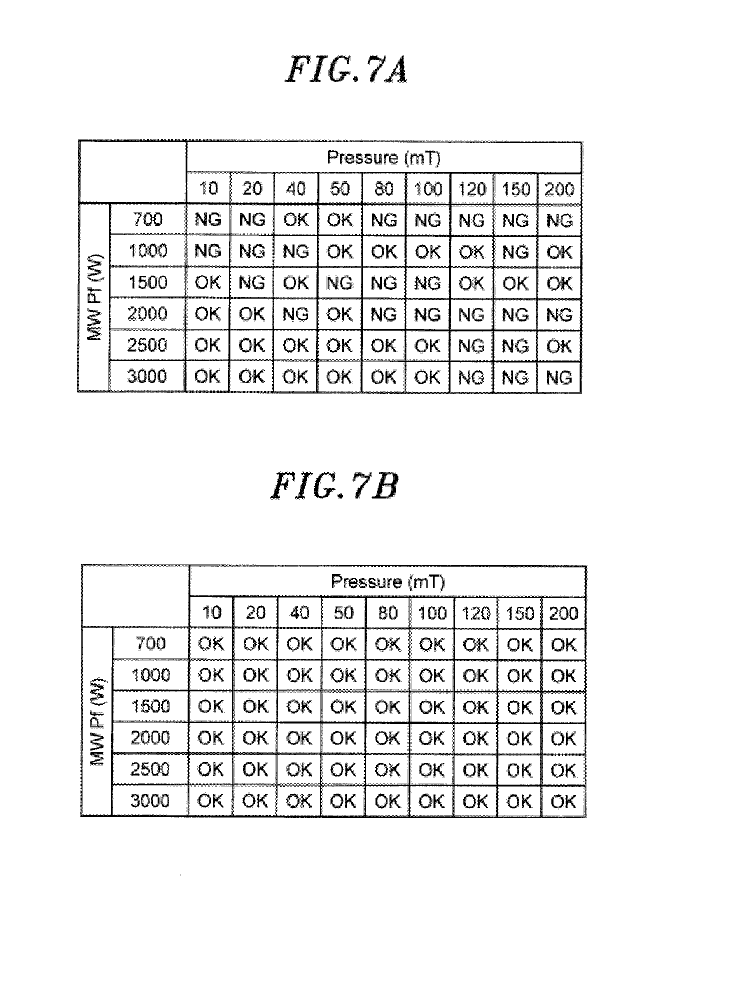

FIGS. 7A and 7B are graphs showing whether or not a plasma is stable under various pressures and powers (FIG. 7A shows the test example of FIG. 4 and FIG. 7B shows the test example of FIG. 6).

In the structure of the test example shown in FIG. 4, the width W₁ of the inner slot was set to about 14 mm and the width W₃ of the outer slot was set to 10 mm. In the structure of the test example shown in FIG. 6, the width W₁ of the inner slot was set to about 6 mm and the width W₃ of the outer slot was set to 6 mm. The RF power applied to the electrostatic chuck in the plasma processing apparatus was set to about 250 W. N₂ and Cl₂ were introduced into the processing chamber at flow rates of about 300 sccm and 100 sccm, respectively. The RDC value was set to about 30%. The substrate temperature was set to 30° C. The measurement time was set to about 30 sec.

In that case, referring to FIG. 7A showing the test example of FIG. 4, the plasma was stable (OK) when the pressure (mT) in the processing chamber was low and the microwave power (MW Pf (W)) was high. However, the the plasma was flickered (NG) under the other conditions in an eye observation. 1 mT (milliTorr) is about 133 mPa.

Meanwhile, referring to FIG. 7B showing the test example of FIG. 6, the plasma was stable (OK) under all conditions including the pressure ranging from about 10 mT to 200 mT and the power ranging from about 700 W to 3000 W.

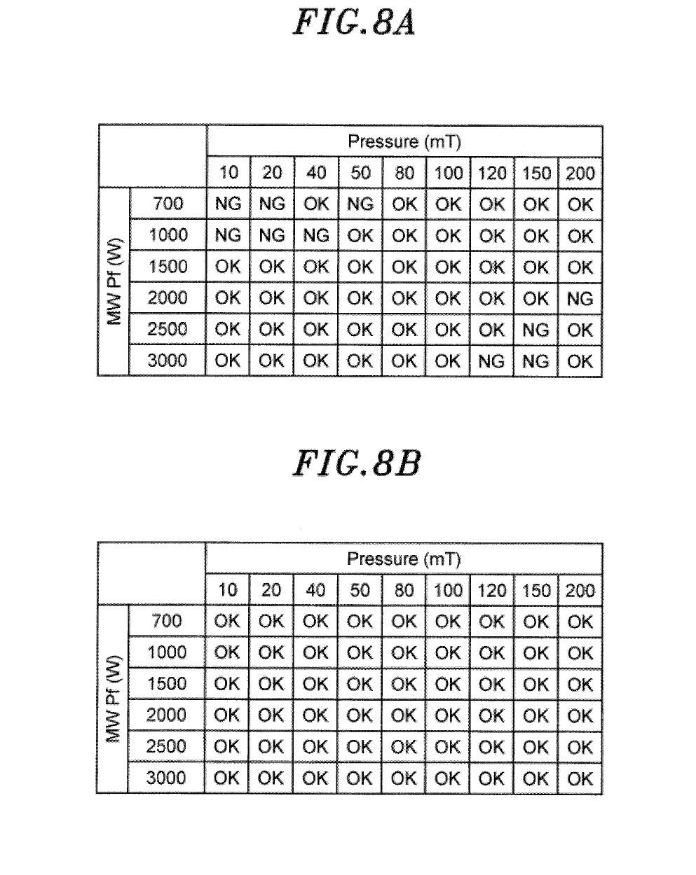

FIGS. 8A and 8B are graphs showing whether or not misfire occurs under various pressures and powers (FIG. 8A shows the test example of FIG. 4 and FIG. 8B shows the test example of FIG. 6). The test conditions are the same as those in FIGS. 7A and 7B.

In this case, referring to FIG. 8A showing the test example of FIG. 4, the misfire occurred (NG) when both of the pressure (mT) in the processing chamber and the microwave power (MW Pf (W)) were low and when both of the pressure (mT) and the microwave power (MW Pf (W)) were high. The misfire of the plasma was not monitored (OK) under the other conditions.

Meanwhile, referring to FIG. 8B showing the test example of FIG. 6, the misfire of the plasma was not monitored (OK) under all conditions including the pressure ranging from about 10 mT to 200 mT and the power ranging from about 700 W to 3000 W.

As described above, both of the stability of the plasma and the function of misfire prevention were better in the structure of the test example shown in FIG. 6. However, the in-plane uniformity of the plasma was improved in the structure of the test example shown in FIG. 4.

The antenna includes the dielectric window and the slot plate provided at one side of the dielectric window. The slot plate has the inner slot groups 133 and 134 and the outer slot groups 133′ and 134′ which are arranged in a concentric circular shape about the center of the slot plate. The outer slot groups 133′ and 134′ are provided at both of positions overlapped with the second recesses 153 and positions that are not overlapped with the second recesses 153. Accordingly, the stability of plasma and the function of misfire prevention can be improved.

While the invention has been shown and described with respect to the embodiments, it will be understood by those skilled in the art that various changes and modifications may be made without departing from the scope of the invention as defined in the following claims.

What is claimed is:

1. A dielectric window at one surface of which a slot plate is to be disposed, comprising:
at the other surface of the dielectric window, a flat surface surrounded by an annular first recess and a plurality of second recesses formed at a bottom surface of the first recess.

2. An antenna comprising:
the dielectric window described in claim 1; and
the slot plate provided at the one surface of the dielectric window.

3. The antenna of claim 2, wherein the slot plate includes a plurality of slot pairs, each being formed of two slots, and
wherein the plurality of slot pairs is concentrically arranged about a centroid position of the slot plate and arranged such that straight lines extending from the centroid position of the slot plate and passing through two slots of each slot pair are not overlapped with each other.

4. The antenna of claim 2, wherein the slot plate includes:
a first slot group having a plurality of slots spaced from the centroid position of the slot plate by a first distance;
a second slot group having a plurality of slots spaced from the centroid position of the slot plate by a second distance;
a third slot group having a plurality of slots spaced from the centroid position of the slot plate by a third distance;
a fourth slot group having a plurality of slots spaced from the centroid position of the slot plate by a fourth distance,
wherein the first to the fourth distance have a relationship of the first distance<the second distance<the third distance<the fourth distance;
slots of the first slot group and slots of the second slot group which correspond to each other form a plurality of first slot pairs and slots of the third slot group and slots of the fourth slot group which correspond to each other form a plurality of second slot pairs;
the slot of the second slot group of each first slot pair is positioned on a first straight line extending from the centroid position of the slot plate and passing through the slot of the first slot group of the first slot pair;
the slot of the fourth slot group of each second slot pair is positioned on respective second straight lines extending from the centroid position of the slot plate and passing through the slot of the third slot group of the corresponding second slot pair; and
the slots are arranged such that the first straight line and the second straight line are not overlapped with each other.

5. The antenna of claim 4, wherein when seen from a direction perpendicular to a main surface of the slot plate, the flat surface surrounded by the first recess is overlapped with the first slot group and the second recesses are overlapped with at least one of the slots of the third slot group and the slots of the fourth slot group.

6. The antenna of claim 4, wherein the number of the slots of the first slot group and the number of the slots of the second slot group are the same number denoted by N1; and
the number of the slots of the third slot group and the number of the slots of the fourth slot group are the same number denoted by N2,
wherein N2 is an integer multiple of N1.

7. The antenna of claim 4, wherein a slot width of the first slot group is the same as a slot width of the second slot group;
a slot width of the third slot group is the same as a slot width of the fourth slot group; and
the slot width of the first slot group and the slot width of the second slot group are greater than the slot width of the third slot group and the slot width of the fourth slot group.

8. The antenna of claim 4, wherein an angle between straight line extending from the centroid position of the slot plate and passing through the centroid of each slot and a lengthwise direction of the corresponding slot is the same in each of the first to the fourth slot group;
the slot of the first slot group and the slot of the second slot group which are positioned on the same straight line extending from the centroid position of the slot plate are elongated in different directions; and
the slot of the third slot group and the slot of the fourth slot group which are positioned on the same straight line extending from the centroid position of the slot plate are elongated in different directions.

9. The antenna of claim 2, wherein the second recesses have a circular shape in a plane view.

10. A plasma processing apparatus comprising:
the antenna described in claim 2;
a processing chamber having the antenna at a ceiling portion thereof;
a mounting table, provided in the processing chamber to face the other surface of the dielectric window, for mounting thereon a substrate to be processed; and
a microwave generator configured to supply a microwave to the antenna.

11. An antenna comprising:
the dielectric window described in claim 1; and
the slot plate provided at the one surface of the dielectric window;
wherein the slot plate includes an inner slot group and an outer slot group which are concentrically arranged about the centroid position of the slot plate; and
slots of the outer slot group are provided at both of positions overlapped with the second recesses and positions that are not overlapped with the second recesses.

12. The antenna of claim 11, wherein a width of each slot of the inner slot group is 6 mm±6 mm×0.2.
